(19) United States
(12) Patent Application Publication
(10) Pub. No.: US 2008/0055865 A1
(43) Pub. Date: Mar. 6, 2008

(54) HEAT SINK FIXING ASSEMBLY

(75) Inventor: Lien-Tsung Yeh, Taipei (TW)

Correspondence Address: WORKMAN NYDEGGER, 60 EAST SOUTH TEMPLE, 1000 EAGLE GATE TOWER, SALT LAKE CITY, UT, 84111, US

(73) Assignee: INVENTEC CORPORATION, Taipei (TW)

(21) Appl. No.: 11/468,636

(22) Filed: Aug. 30, 2006

(51) Int. Cl. H05K 7/20

(52) U.S. Cl. 361/719

(57) ABSTRACT

A heat sink fixing assembly used for fixing the heat sink on a circuit board is provided, which includes a base and a fixing portion extending there-from, wherein the base is made of an elastic material with a slot formed thereon. When the heat sink extends into the slot and thus is pressed and held by the base fixed on the circuit board by the fixing portion, the heat sink fixing assembly is capable of accurately adjusting the force for clipping the heat sink.

### BACKGROUND OF THE INVENTION

1. Field of Invention

The present invention relates to a heat sink fixing assembly, and more particular to a heat sink fixing assembly for adjusting the force for clipping the heat sink and thereby reducing the number of elements.

2. Related Art

Heat is produced during the process of executing calculations by electronic elements for computer equipments, such as a chip of the central processing unit (CPU) and a power integrated circuit. Due to increasingly high watt consumption for the chip of CPU and the concentrated heat source caused by high integration of the integrated circuit, not only a high heat is produced during the operation, but also the higher the operation speed is, the more heat is produced. Since the operation temperature has a strong impact on whether the computer equipment is crash or not, appropriately controlling the temperature causes a higher reliability of the computer equipment and maintains a stable operation of an exothermic electronic element.

In order to reduce the operation temperature of the exothermic electronic element and thereby maintaining its effective operation, various heat sinks are designed through the heat sink design. For example, considering shortening the heat transfer path, the heat sink is directly disposed on one end surface of the exothermic electronic element, so as to transmit the heat produced by the exothermic electronic element and thereby discharging the heat to outside. The fixing assembly for fixing the heat sink also plays an important role, because it is used for contacting the compact heat sink with the exothermic electronic element, besides fixing the heat sink. If the clip force applied to the heat sink by the fixing assembly is too small, the heat sink is unavoidably dropped off and deformed when the structure is tested, such as a vibration test, a shock test, and a loading test. If the clip force is too large, the force for the heat sink to press the chip is also too large, such that the solder balls on the chip of CPU are damaged, thereby resulting in the failure of its original function. Therefore, when the heat sink is tested, such as a shock test or a loading test, if the clip force of the fixing assembly is not appropriately adjusted, the operation state of the heat sink is surely influenced.

As shown in FIG. 1A, it is a stereogram of an appearance for a conventional heat sink fixing assembly with a heat sink fixed thereon. A heat sink 10a has a plurality of paralleled heat sink fins and is pressed on one surface of an electronic element 20a, the other surface of the electronic element 20a is disposed on a motherboard 30a. The heat sink 10a is provided with a fastener 41a and a locking component 42a at the opposite two sides respectively for fixing the heat sink 10a on the motherboard 30a. The fastener 41a is disposed to pass through both the slot and a support base 31a on the heat sink 10a, so as to ensure the heat sink 10a to be pressed on the electronic element 20a.

As shown in FIGS. 1A, 1B, and 1C, the locking component 42a comprises a snapping component 43a and a snapping base 44a. The snapping component 43a has a first through-hole 431a and a snapping portion 432a bending and extending from the edge of the first through-hole 431a. The snapping portion 432a has chamfers in various directions (as shown in FIG. 1B), and the snapping base 44a has a crossbeam 441a and a snapping opening 442a at opposite two ends of the crossbeam 441a. Also, a second through-hole 443a is located on the crossbeam 441a corresponding to the first through-hole 431a (as shown FIG. 1C). The snapping component 43a passes through the snapping opening 442a with the snapping portion 432a, such that the chamfers in various directions of the snapping portion 432a are clipped with the snapping opening 442a, and thereby the first through-hole 431a and the second through-hole 443a are aligned with each other, and a screwing component 50a is configured to pass through the heat sink 10a, the first through-hole 431a, the second through-hole 443a, and the motherboard 30a, the snapping component 43a, and the snapping base 44a, thereby achieving a snapping effect.

It is found from the conventional heat sink fixing assembly that, its assembling procedure is complex; a great number of parts are required, thereby resulting in a high cost in mold splitting. When the shock and loading tests are performed, since the fixing assembly is composed of multiple parts, the structural strength after the assembly is weak, and thereby loosing and cracking easily occur at X, Y, and Z axes, which reduces the clip force, thus, the effect of pressing the heat sink between the chips of CPU becomes relatively undesirable.

Additionally, as disclosed in U.S. Patent Publication U.S. Pat. No. 6,552,905, the heat sink is maintained to be snapped by utilizing a screw, a blade spring, and a washer. Since the design of the blade spring and the washer buffers the vibration of the heat sink generated during an actual operation, but the problem of too many parts and the problem of loosing caused by a low combining strength will still occur.

In U.S. Patent Publication U.S. Pat. No. 6,829,143, the heat sink is fixed on the motherboard by a snapping structure composed of a screw, a spring, and a unidirectional snapping element. The screw passes through the spring and the unidirectional snapping element and is fixed to the bolt protruding from the motherboard. Since the heat sink is fixed on the motherboard indirectly through the bolt, the structural strength of the heat sink is reduced and thereby resulting in the problem of loosing.

### SUMMARY OF THE INVENTION

In view of the above problems in the conventional art, such as a complex mounting procedure and an increasing cost in mold splitting due to too many parts, and the loosing problem occurred after the parts are assembled during the shock and loading tests, an object of the present invention is to provide a heat sink fixing assembly for experiencing the shock and loading tests and reducing the number of elements.

To achieve the object, a heat sink fixing assembly is disclosed in the present invention, which is used for fixing the heat sink with a flange on a circuit board. The heat sink fixing assembly comprises a base and a fixing portion, wherein the base is made of an elastic material and has a top wall and a plurality of side walls extending from periphery edges of the top wall, thereby forming a slot for accommodating the flange, and the fixing portion is provided with at least one fixing hole, and the base is fixed on the circuit board by a mounting component passing through the fixing holes.

To achieve the object, a heat sink fixing assembly is further disclosed in the present invention, which is used for fixing the heat sink with a flange on a circuit board. The heat sink fixing assembly comprises a base, a fixing portion and a fastener, wherein the base is made of an elastic material and has a top wall and a plurality of side walls extending from periphery edges of the top wall, thereby forming a slot for accommodating the flange; the fixing portion is provided with at least one fixing hole, wherein the base is fixed on the circuit board by a mounting component passing through the fixing holes; and the fastener is fixed on the circuit board for pressing against the heat sink.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, which thus is not limitative of the present invention, and wherein:

FIG. 1A is a diagram of using state of a conventional heat sink fixing assembly.

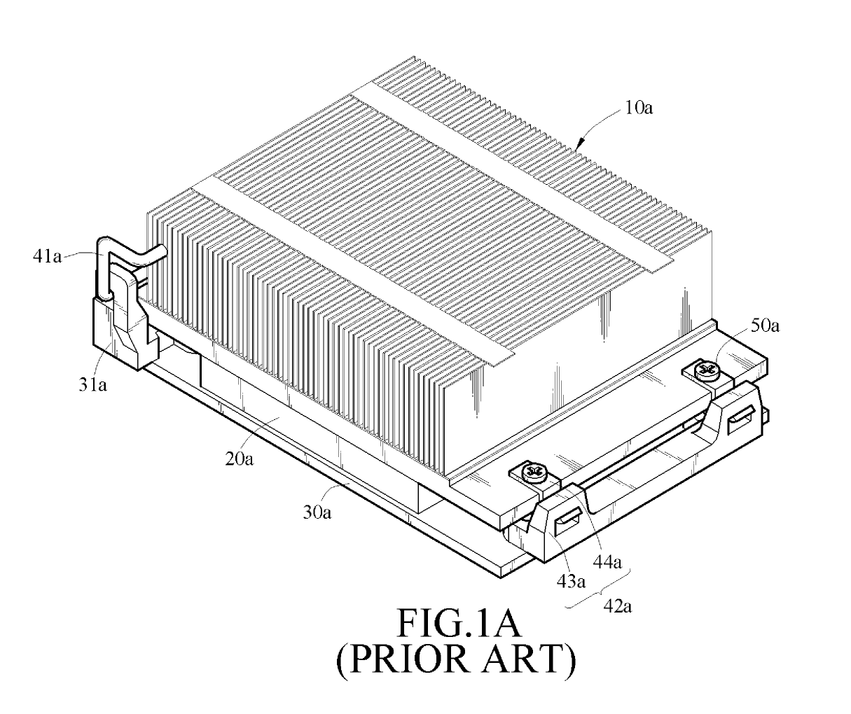

FIG. 1B is a stereogram for an appearance of a snapping component of a conventional heat sink fixing assembly.

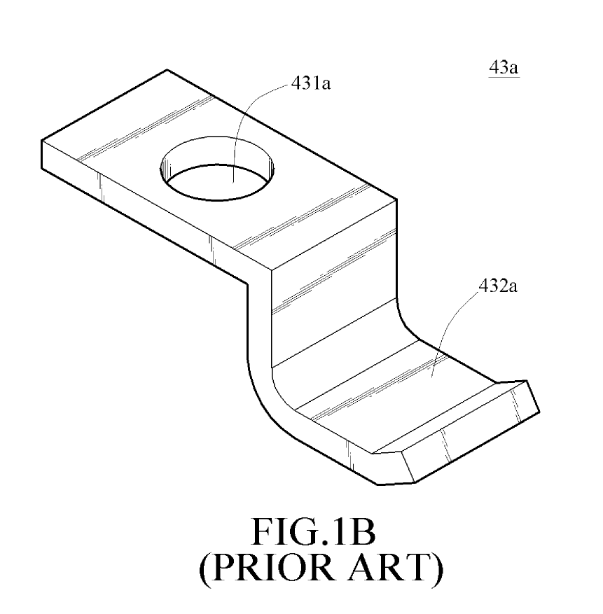

FIG. 1C is a stereogram for an appearance of a snapping base of a conventional heat sink fixing assembly.

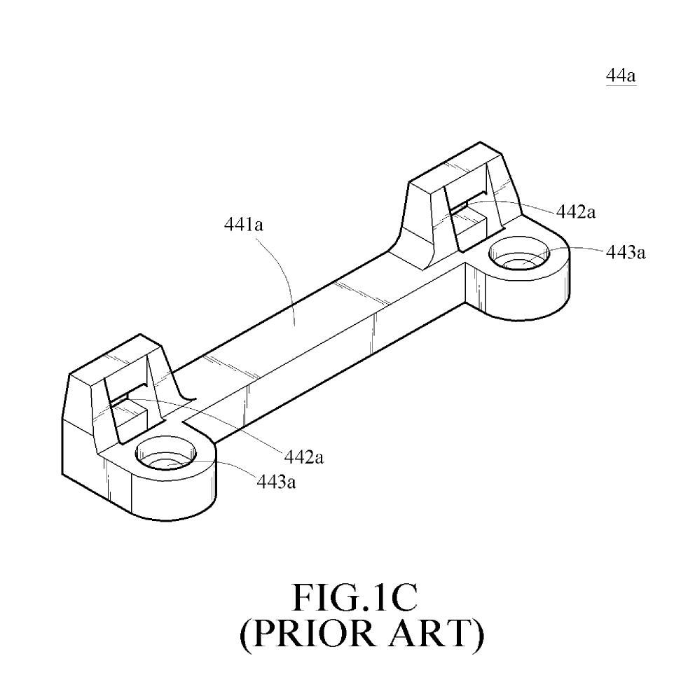

FIG. 2 is a stereogram of an appearance according to a first embodiment of the present invention.

FIG. 3 is a diagram of using state according to the first embodiment of the present invention.

FIG. 4 is a stereogram of an appearance according to a second embodiment of the present invention.

### DETAILED DESCRIPTION OF THE INVENTION

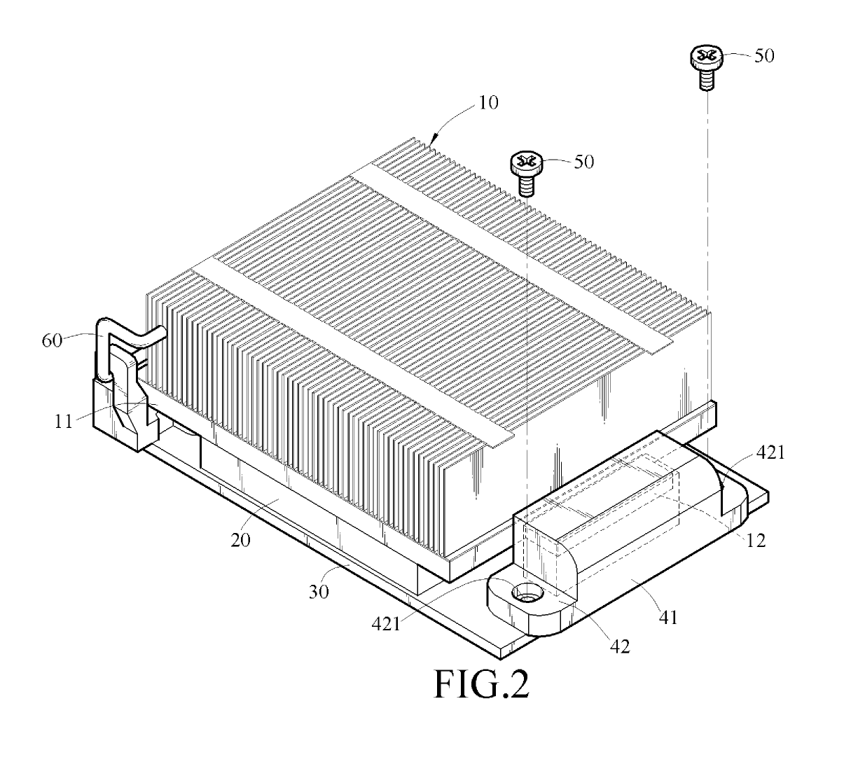

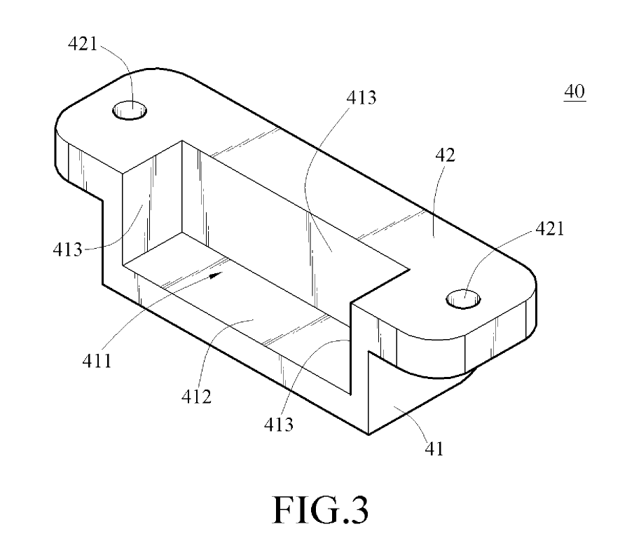

As shown in FIGS. 2 and 3, they show a heat sink fixing assembly according to a first embodiment of the present invention. The fixing assembly comprises a fastener 60 and a fixing portion 40, wherein the fastener 60 is disposed on a circuit board 30 for pressing a heat sink 10; the fixing portion 40 is used for fixing one side edge of the heat sink 10, thereby the heat sink 10 is pressed to an electronic element 20 on the circuit board 30. Therefore, the heat produced by the electronic element 20 is transferred to the heat sink 10, through which the heat is dissipated. Such an electronic element 20 is an electronic chip with a high power, for example, a central processing unit (CPU), a graphic chip, or a system chipset, thus, the heat produced during the operation must be dissipated through the heat sink 10.

Referring to FIGS. 2 and 3, the fixing portion 40 comprises a body base 41 and two fixing portions 42. The base 41 is made of the elastic material and has a top wall 412 and a plurality of side walls 413 extending from periphery edges of the top wall 412, thereby the top wall 412 and the plurality of side walls 413 together form a slot 411. The two fixing portions 42 extend from the opposite two end surfaces of the base 41 respectively, wherein each of the fixing portions 42 is provided with at least one fixing hole 421 respectively for a mounting component 50 to pass through, thereby being fixed on the circuit board 30, and thus the fixing portion 40 is fixed on the circuit board 30.

In FIGS. 2 and 3, the heat sink 10 has a pressing portion 11 and a flange 12 positioned on its opposite two side edges respectively. The pressing portion 111 is slot-shaped for accommodating a fastener 60, such that the fastener 60 is elastically pressed on the heat sink 10. The width of the flange 12 is slightly smaller than that of the slot 411 of the fixing portion 40, thus, the slot 411 is just suitable for accommodating the flange 12, and thereby fixing one side edge of the heat sink 10.

When the heat sink 10 is to be fixed on the electronic element 20, the flange 12 of the heat sink 10 is inserted into the slot 411 of the fixing portion 40, such that one side edge of the heat sink 10 is restricted. Next, the heat sink 10 is adjusted to substantially contact the electronic element 20. Then, the fastener 60 is placed within the pressing portion 11, and thereby being elastically pressed on the heat sink 10. Since the flange 12 on one side of the heat sink 10 is inserted into the slot 411 of the fixing portion 40 for fixing one side edge of the heat sink 10, such that the heat sink 10 is evenly pressed on the electronic element 20 when being pressed by the fastener 60, thus, the inclining phenomenon caused by a unilateral pressing of the fastener 60 is avoided.

Also, the thickness of the top wall 412 for the base 41 may change, such that the position of the flange 12 relatively to the circuit board 30 is controlled, thereby, the clip force applied to the heat sink 10 is more accurately regulated and meanwhile, the fixing force of the fastener 60 and that of the fixing portion 40 being applied to the heat sink 10 are balanced, so as to ensure the heat sink 10 to be evenly pressed on the electronic element 20. The base 41 is made of an elastic material, such that it produces an appropriate holding power to the heat sink 10, thus, the heat sink 10 is evenly pressed on the electronic element 20 completely.

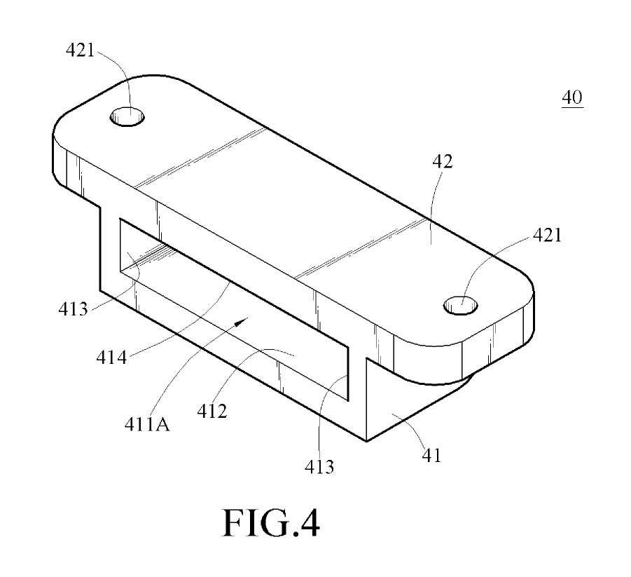

As shown in FIG. 4, it shows the fixing portion 40 according to a second embodiment of the present invention. Such fixing portion 40 also comprises a base 41 and a fixing portion 42, which differs from the one of the first embodiment in that, the base 41 has a top wall 412, two side walls 413, and a bottom wall 414 opposite to the top wall 412, and a slot 411A is formed by the top wall 412, the side walls 413, and the bottom wall 414. The fixing portion 42 is configured to be extended from the two opposite end surfaces of the base 41 and provided with a plurality of fixing holes 421. In the first embodiment, the opening direction of the slot 411 faces the bottom and one side surface of the base 41, and in the second embodiment, the opening direction of the slot 411A only faces one side surface of the base 41. According to the application steps of the first embodiment, when the flange 12 of the heat sink 10 is inserted, a change in the thickness of the top wall 412 and the bottom wall 414 occurs in the pressing direction. One snapping surface is formed in the first embodiment of the present invention, two snapping surfaces are formed in the second embodiment, such that the snapping force is more accurately controlled.

The heat sink fixing assembly disclosed in the present invention is not only applied to heat sinks of different sizes, but also enables any forms of heat sinks to be directly fixed on the motherboard and thereby being convenient for mounting. In addition, the design of a single element achieves the effect of reducing the number of the parts. Further, the base is made of an elastic material, such that it absorbs the deformation in various directions to relieve the loosing during the shock and loading tests. Furthermore, there is a change in the thickness of the base in the direction of pressing the heat sink, thereby controlling the value of the clip force for the heat sink more accurately.

The present invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A heat sink fixing assembly for fixing a heat sink with a flange on a circuit board, comprising:
a base having a slot for accommodating the flange; and
a fixing portion extending from the base and being fixed on the circuit board.

2. The heat sink fixing assembly as claimed in claim 1, wherein the base is made of an elastic material.

3. The heat sink fixing assembly as claimed in claim 1, wherein the base has a top wall and a plurality of side walls extending from periphery edges of the top wall, and the slot is formed between the top wall and the side walls.

4. The heat sink fixing assembly as claimed in claim 3, wherein the base further comprises a bottom wall opposite to the top wall.

5. The heat sink fixing assembly as claimed in claim 1, wherein the fixing portion is provided with at least one fixing hole for being passed through by a mounting component and thereby the fixing portion is fixed on the circuit board.

6. A heat sink fixing assembly used for fixing a heat sink with a flange on a circuit board, comprising:
a base having a slot for accommodating the flange;
a fixing portion extending from the base and being fixed on the circuit board; and
a fastener fixed on the circuit board for pressing the heat sink.

7. The heat sink fixing assembly as claimed in claim 6, wherein the base is made of an elastic material.

8. The heat sink fixing assembly as claimed in claim 6, wherein the base has a top wall and a plurality of side walls extending from periphery edges of the top wall, and the slot is formed between the top wall and the side walls.

9. The heat sink fixing assembly as claimed in claim 8, wherein the base further comprises a bottom wall opposite to the top wall.

10. The heat sink fixing assembly as claimed in claim 6, wherein the fixing portion is provided with one fixing hole for being passed through by a mounting component and, thereby the fixing portion is fixed on the circuit board.

11. The heat sink fixing assembly as claimed in claim 6, wherein the heat sink further has a pressing portion opposite to the flange, which is used for accommodating the fastener and thereby elastically pressing against the heat sink.
